(19) United States
(12) Patent Application Publication
(10) Pub. No.: US 2009/0194831 A1
(43) Pub. Date: Aug. 6, 2009

(54) INTEGRATED CAVITY IN PCB PRESSURE SENSOR

(75) Inventors: Gary L. CASEY, Thousand Oaks, CA (US); Saleh AHMED, Simi Valley, CA (US)

Correspondence Address: JEFFER, MANGELS, BUTLER & MARMARO, LLP, 1900 AVENUE OF THE STARS, 7TH FLOOR, LOS ANGELES, CA, 90067, US

(73) Assignee: CUSTOM SENSORS & TECHNOLOGIES, INC., Moorpark, CA (US)

(21) Appl. No.: 12/024,975

(22) Filed: Feb. 1, 2008

(51) Int. Cl. G01L 9/06; H05K 3/36; H01R 12/00

(52) U.S. Cl. 257/419; 29/830; 439/74

(57) ABSTRACT

Described herein is an integrated pressure sensor assembly. The integrated pressure sensor assembly includes a printed circuit board assembly comprising a plurality of boards; a pressure die mounted on at least a portion of the printed circuit board assembly; and a housing engaged to the printed circuit board assembly. The printed circuit board assembly includes at least one pressure transmission channel and at least one electrical transmission channel.

### FIELD OF THE INVENTION

The present invention relates generally to pressure sensors, and more specifically to PCB pressure sensors.

### BACKGROUND OF THE INVENTION

A channel and/or cavity for the transmission of pressure in a pressure sensor is typically created in the assembly structure by molding, forming, welding, joining, machining, etc. of plastics and metal parts. Often times, this is expensive and creates a difficult assembly process. In this regard, there is a need for a pressure sensor assembly with the pressure channel, circuit layout, and mounting feature, and other components, all contained within the same structure.

### SUMMARY OF THE PREFERRED EMBODIMENTS

According to a first aspect of the present invention, there is provided an integrated pressure sensor assembly. The integrated pressure sensor assembly includes a printed circuit board assembly comprising a plurality of boards; a pressure die mounted on at least a portion of the printed circuit board assembly; and a housing at least partially surrounding the printed circuit board assembly. The printed circuit board assembly includes at least one pressure channel and at least one electrical channel. Preferably, the printed circuit board assembly comprises a bottom board; a top board; and at least one center board disposed between the top and bottom boards. The top board preferably comprises a first opening and a second opening that each partially define a portion of the pressure channel. Preferably, the at least one center board includes a first opening, wherein the first opening in the at least one center board is in flow communication with the first opening in the top board. Preferably, the first opening in the at least one center board is a slot, and wherein the first opening in the at least one center board is in flow communication with the second opening in the top board.

According to another aspect of the present invention, there is provided a method including providing a printed circuit board assembly comprising a bottom board; top board; and at least one center board disposed between the top and bottom boards. The method also includes providing a pressure die disposed on at least a portion of the printed circuit board assembly, and providing a housing. The housing at least partially surrounds the printed circuit board assembly. Preferably, the printed circuit board assembly includes at least one fluid transmission channel and at least one electrical transmission channel. Preferably, the method further includes the step of defining a first opening and a second opening in the top board, wherein each partially define a portion of the fluid transmission channel. Preferably, the method further includes the step of defining a first opening in the at least one center board, wherein the first opening in the at least one center board is a slot, and wherein the first opening in the at least one center board is in flow communication with the second opening in the top board. Preferably, the method further includes the step of aligning the first and second openings on the top board with the first opening on the center board to at least partially define the fluid transmission channel.

According to another aspect of the present invention, there is provided a printed circuit board assembly. The printed circuit board assembly preferably includes a bottom board, a top board, and at least one center board disposed between the top and bottom boards. The printed circuit board assembly preferably includes at least one fluid channel and at least one electrical channel at least partially therethrough. In one embodiment, the fluid channel preferably extends through at least two of the top, bottom, and center boards. In one embodiment, the fluid channel preferably provides flow communication between at least two of the boards and wherein the electrical channel provides electrical communication between at least two of the boards. In one embodiment, the printed circuit board assembly includes a pressure die or sense element at least partially disposed on a portion of the printed circuit board assembly, wherein the pressure die or sense element measures pressure in the fluid channel. Preferably, the sense element is at least partially disposed over a first opening on the top board, wherein the first opening at least partially defines the fluid channel.

### BRIEF DESCRIPTION OF THE DRAWINGS

The invention may be more readily understood by referring to the accompanying drawings in which:

FIG. 1 is a bottom perspective view of the integrated pressure sensor assembly in accordance with an embodiment of the present invention;

FIG. 2 is a top perspective view of the integrated pressure sensor assembly of FIG. 1;

FIG. 3 is an exploded perspective view of the integrated pressure sensor assembly of FIG. 1;

FIG. 4 is a perspective view of the printed circuit board assembly of the integrated pressure sensor assembly of FIG. 1;

FIG. 5A is an exploded top perspective view of an embodiment of the printed circuit board assembly of the integrated pressure sensor assembly of FIG. 1;

FIG. 5B is an exploded bottom perspective view of the printed circuit board assembly of FIG. 5A;

FIG. 6A is an exploded top perspective view of another embodiment of the printed circuit board assembly of the integrated pressure sensor assembly of FIG. 1;

FIG. 6B is an exploded bottom perspective view of the printed circuit board assembly of FIG. 6A;

FIG. 7 is a top plan view of the printed circuit board assembly of the integrated pressure sensor assembly if FIG. 1;

FIG. 8 is a cross-section of the printed circuit board assembly of the integrated pressure sensor assembly of FIG. 1, taken along 8-8 of FIG. 7;

FIG. 9 is a top plan view of the integrated pressure sensor assembly of FIG. 1;

FIG. 10 is a cross-section of the integrated pressure sensor assembly of FIG. 1, taken along line 10-10 of FIG. 9; and

FIG. 11 is a bottom plan view of the bottom board of the printed circuit board assembly of the integrated pressure sensor assembly of FIG. 1.

Like numerals refer to like parts throughout the several views of the drawings.

### DETAILED DESCRIPTION OF THE PREFERRED EMBODIMENT

It will be appreciated that terms such as “front,” “back,” “top,” “bottom,” “side,” and the like used herein are merely for ease of description and refer to the orientation of the components as shown in the figures.

Generally, the present invention may be briefly described as follows. Preferably, the integrated pressure sensor assembly of the present invention is a pressure transducer that comprises a housing and a printed circuit board assembly (also referred to herein as “PCB assembly”). Preferably, the housing encloses the PCB assembly. The PCB assembly includes channels or conduits for the transmission of electricity as well channels or conduits for the transmission of pressure. Preferably, channels for the transmission of electricity are separate from the channels for the transmission of pressure. In a preferred embodiment, the PCB assembly includes a plurality of PCB boards (also referred to herein as “boards”). Briefly, both the pressure and the electrical channels (also referred to herein as “electrical transmission channels”) are preferably created by forming holes in the boards and aligning the holes. In a preferred embodiment, the integrated pressure sensor is a pressure transducer. As such, the integrated pressure sensor assembly may include one or more of the following: connection pads (preferably for signal connection), mounting pads, and any other component, such as a capacitator or the like, used in pressure sensors/transducers. For example, the integrated pressure assembly may include a signal conditioning network, and/or a CPU, within the structure itself or outside of the structure.

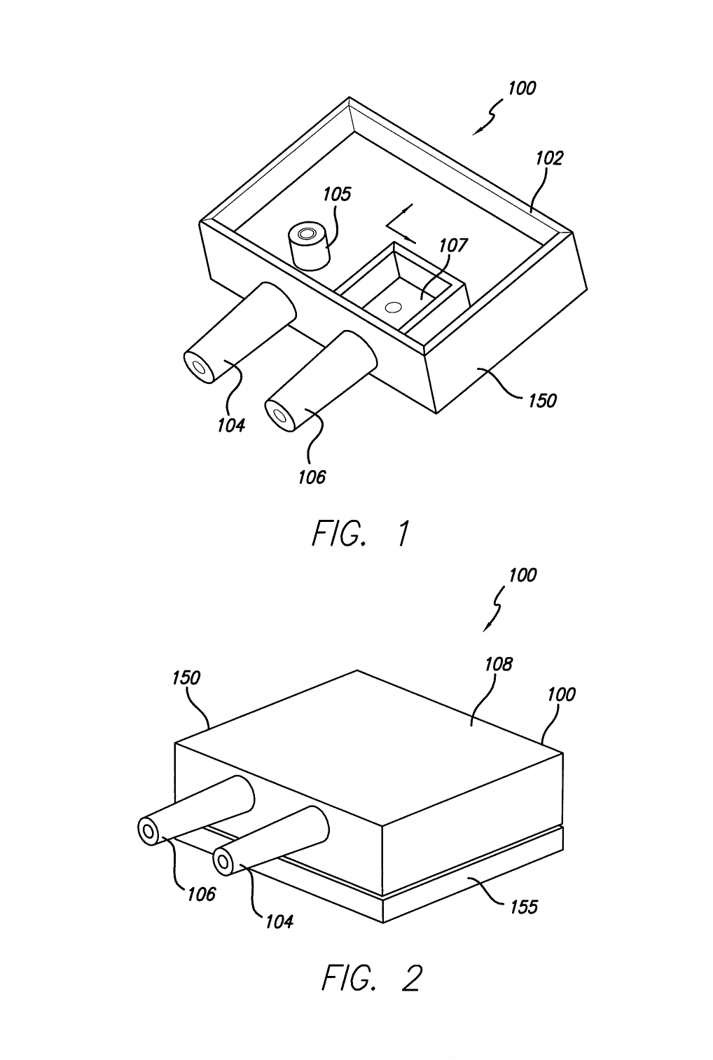

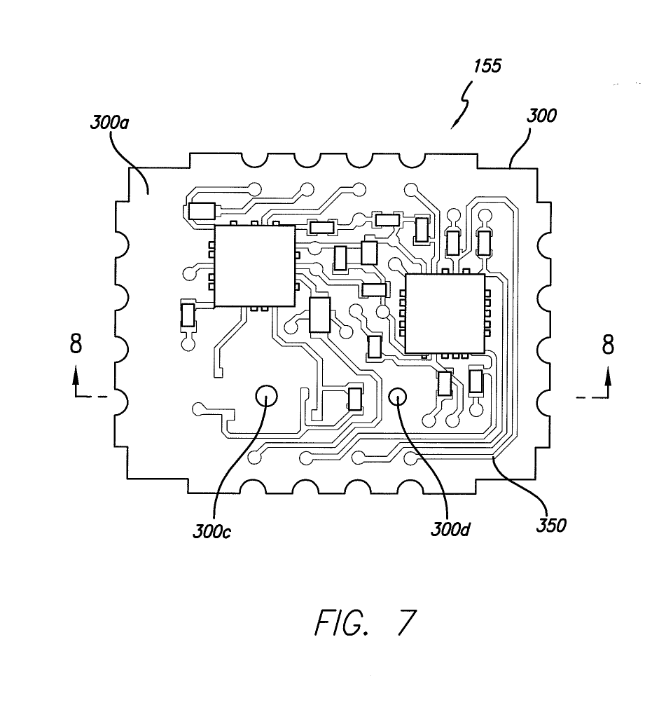

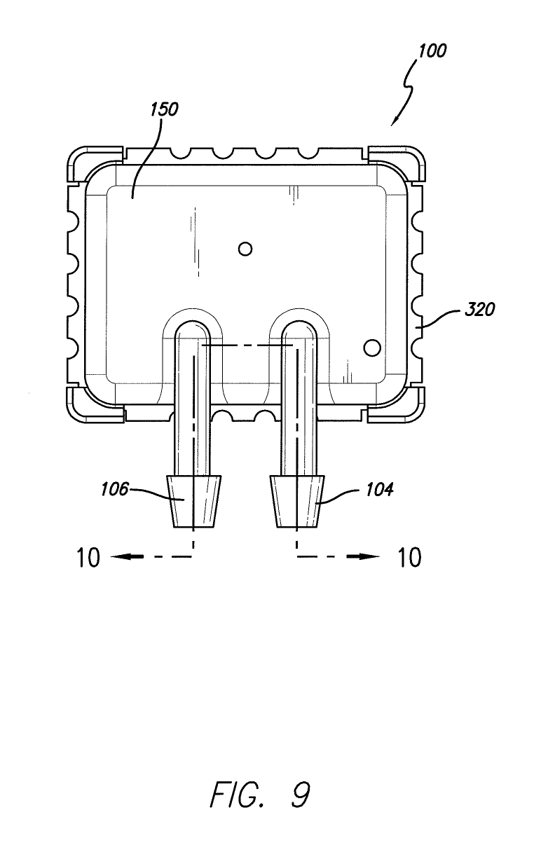

Referring initially to FIGS. 1-11, a preferred embodiment of an integrated pressure sensor assembly 100 of the present invention is described. The integrated pressure sensor assembly 100 preferably includes a housing 150 having a top side, a bottom side 102, pressure ports 104 and 106, chimney 105, and cavity/chamber 107. In a preferred embodiment, the pressure ports 104 and 106 are used for interfacing to outside sources. The chimney 105 is preferably bonded to housing 150, or formed substantially therewith, to form a substantially fluid-tight connection. The housing 150, pressure ports 104 and 106, and chimney 105 are preferably made of plastic, ceramic, or other suitable material.

The inside of chimney 105 is preferably open to the outside of the housing 150. As will be discussed below, pressure die 165 is preferably mounted inside the chimney 105. It is to be understood that integrated pressure sensor assembly 100 may include more than one chimney without departing from the scope of the present invention.

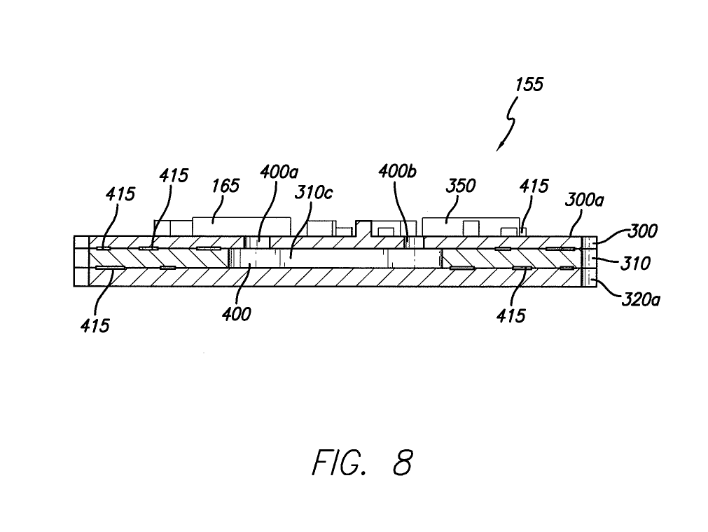

Preferably, the integrated pressure sensor assembly 100 of FIG. 1 is a differential pressure sensor. As such, each of pressure ports 104 and 106 is an intake port. Preferably, one of pressure ports 104 and 106 is a high pressure port, and the other of pressure ports 104 and 106 is a low pressure port. As such, fluid (also referred to herein as “gas”) enters each of pressure ports 104 and 106. Preferably, fluid traveling from the outside of the housing into each of pressure ports 104 and 106 reaches the chimney 105 through pressure channels (also referred to herein as “fluid transmission channels”, “fluid channels”, and “pressure channels”) 400a and 400b (as best seen in FIG. 8) and makes contact with the pressure die 165 (which includes a sense element).

Those skilled in the art will understand that the differential pressure sensor may be used in heating, ventilating, and air conditioning systems (HVAC), among other applications. For example, the differential pressure sensor may be used in an automobile engine for measuring differential pressure in an exhaust system. For example, a high pressure port can be connected via a hose or a conduit to measure the pressure at an engine's exhaust manifold, while a low pressure port can be connected via a conduit to measure the pressure at the engine's intake manifold.

In another embodiment, one of pressure ports 104 and 106 may be an intake port, and the other of pressure ports 104 and 106 may be an outtake or exhaust port. In other embodiments, pressure port 104 or 106 may be omitted, for example when the integrated pressure sensor assembly 100 is used in a gage pressure sensor. Additionally, it is to be understood that the integrated pressure sensor assembly 100 may be any other type of sensor, such as an absolute pressure sensor. As such, the integrated pressure sensor assembly 100 may be vacuum sealed. Preferably, the inside of the structure and the pressure channel are vacuum sealed. However, as discussed above, both pressure ports 104 and 106 may be omitted or more or less pressure ports may be used. The ports may be nozzles, openings, or the like. For example, if the ports are openings, they may not protrude from the structure. It will be understood by those skilled in the art that the number/type and/or configuration of the pressure ports will depend on the type of sensor. The pressure ports may be parallel to a plane defined by the housing (“horizontal port”) and/or perpendicular to the plane defined by the housing (“vertical port”).

As shown in FIG. 2, in a preferred embodiment, the integrated pressure sensor assembly 100 is shown including a housing 150, first and second pressure ports 104 and 106, and a top side 108. Integrated pressure sensor assembly 100 is preferably mounted to a pressure sensor assembly 155.

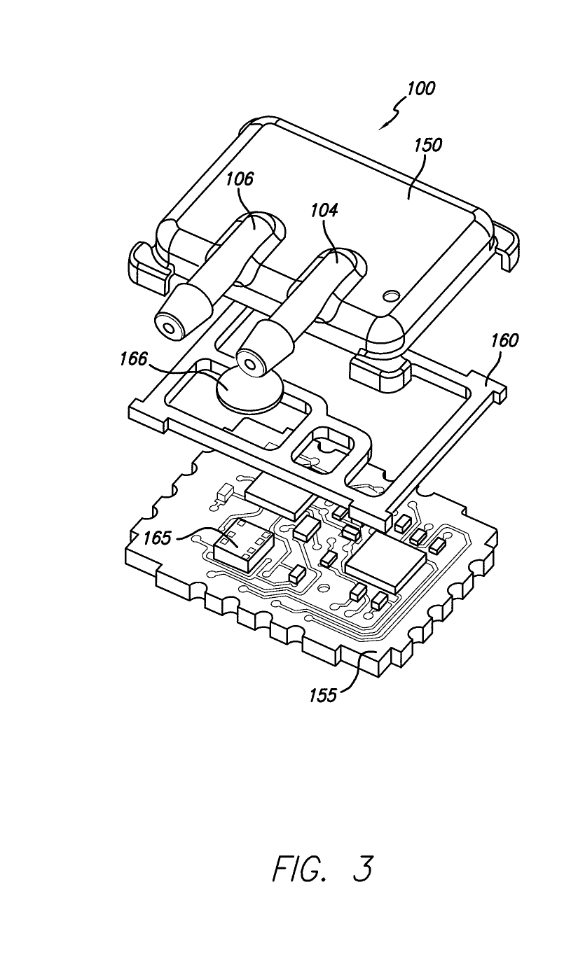

Referring now to FIG. 3, an exploded view of a preferred embodiment of the integrated pressure sensor assembly 100 of the present invention is shown. The integrated pressure sensor assembly 100 preferably includes housing 150 and PCB assembly 155. Preferably, the pressure die 165 (which includes the “pressure-sensing element” or “pressure-sense element” or “sense element”) is disposed on at least a portion of the PCB assembly 155. In a preferred embodiment, housing 150 is secured to PCB assembly 155 using adhesive 160. Preferably, adhesive 160 creates a substantially fluid-tight seal between housing 150 and PCB assembly 155. However, other means of adjoining and/or sealing housing 150 and PCB assembly 155 may be used. As such, housing 150 may be attached to PCB assembly 155 by welding, machining, forming, or the like. For example, PCB assembly 155 may include one or more engagement members, such as fasteners, and housing 150 may include one or more threaded members, or vice versa. Additionally, adhesive 160 may be a gasket, or the like. However, it is to be understood that housing 150 may be omitted or may be replaced by another suitable structure.

As shown in FIG. 3, the integrated pressure sensor assembly 100 may include a filter 166. Filter 166 prevents certain materials from reaching the pressure die 165. Filter 166 may be a hydrophobic filter or a hydrophilic filter. However, in other embodiments, filter 166 may be omitted. Additionally, other means of screening the pressure die 165 from certain elements may used.

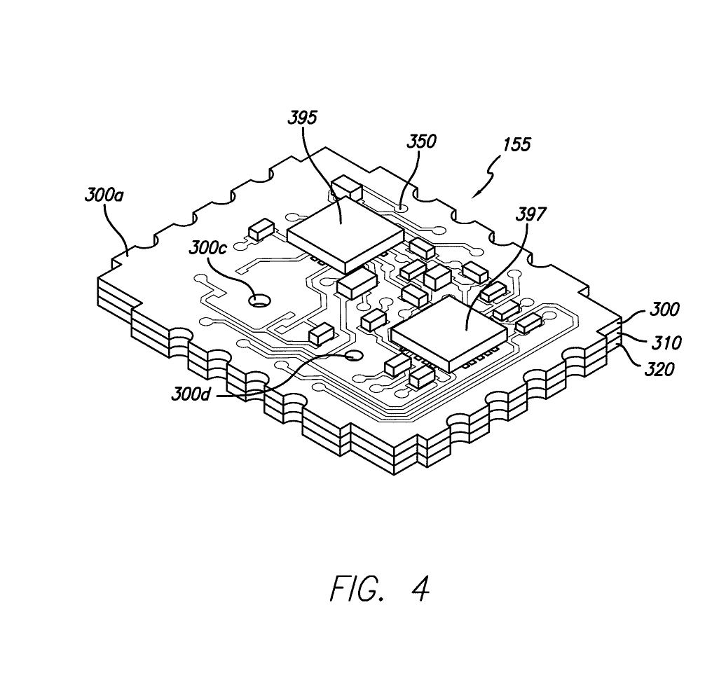

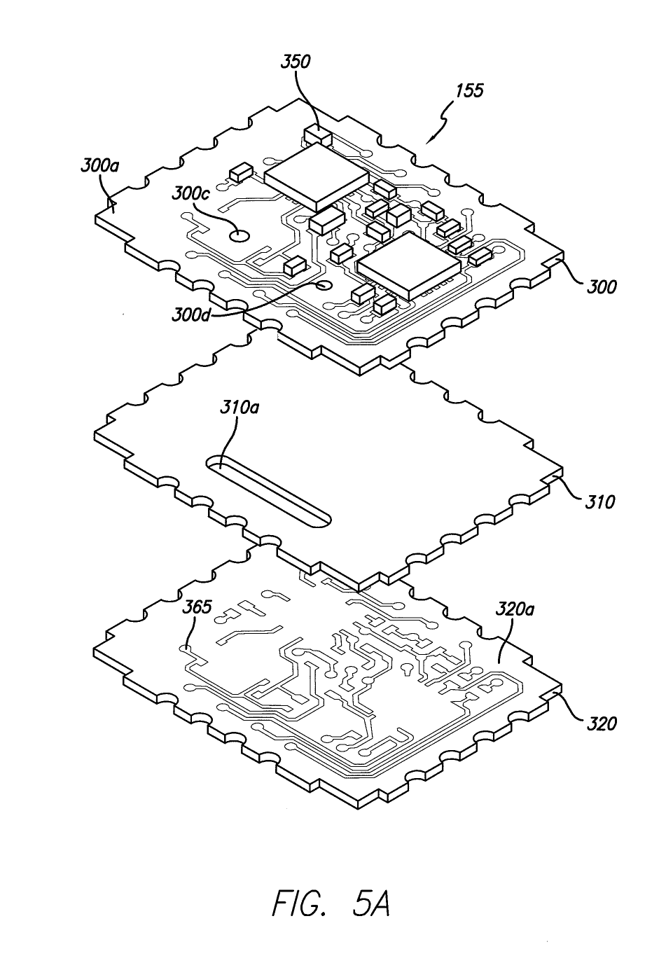

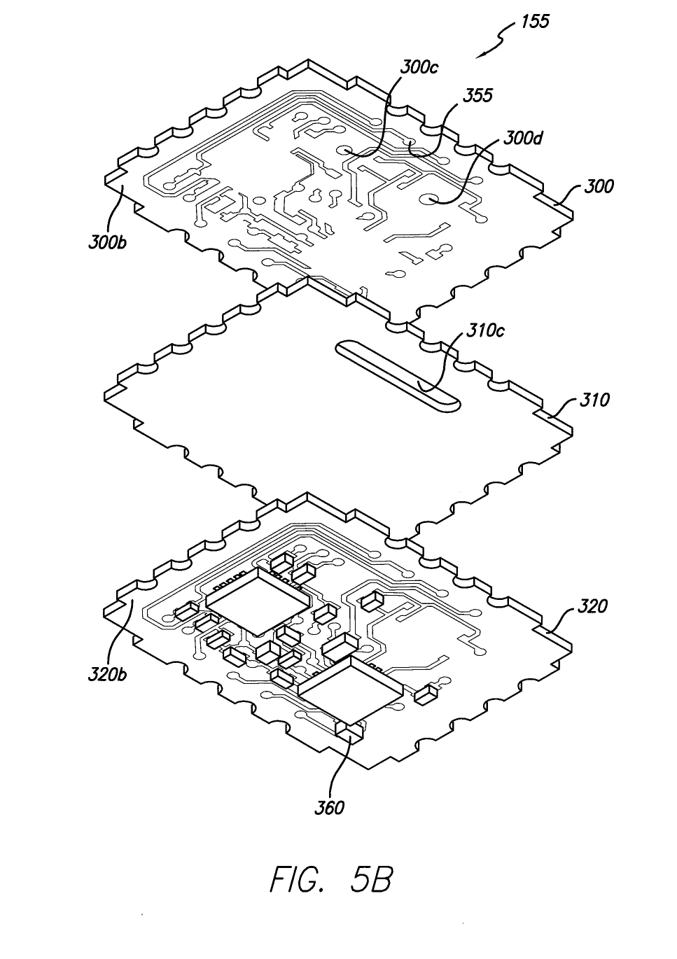

Referring now to FIGS. 4-6B, a preferred embodiment of the PCB assembly 155 is shown. In a preferred embodiment, the PCB assembly 155 includes three PCB boards and four circuit layers 350 and 360, in combination with 355 and 365 or 356 and 366 (as best seen in FIGS. 5A-5B) or “circuit traces.” Preferably, PCB assembly 155 includes a bottom board 320, a center board 310, and a top board 300. In a preferred embodiment, PCB assembly 155 includes first and second openings 300c and 300d. As discussed below, each of these openings defines at least a portion of at least one pressure channel 400. Preferably, the pressure die 165 is disposed on top of opening 300c.

In a preferred embodiment, the boards 300, 310, and 320 are made of FR4 (Flame Retardant 4) material. However, the PCB boards may be made of any polyimide/glass fiber material, ceramic, polyamide, Teflon, any other type of plastic or the like, without departing from the scope of the present invention.

FIG. 5A is an exploded top perspective view, and FIG. 5B is an exploded bottom perspective view, of an embodiment of the PCB assembly 155 of the present invention. As described above, PCB assembly 155 preferably includes top 300, bottom 320, and center 310 boards and four circuit layers. Referring to both FIGS. 5A and 5B, the circuit layers are applied/disposed onto the boards as follows. A first circuit layer 350 is disposed on a top side 300a of the top board 300 and a second circuit layer 360 is disposed on a bottom side 320b of the bottom board 320. A third circuit layer 355 is disposed on a bottom side 300b of the top board 300 and a fourth circuit layer 365 is disposed on a top side 320a of the bottom board 320.

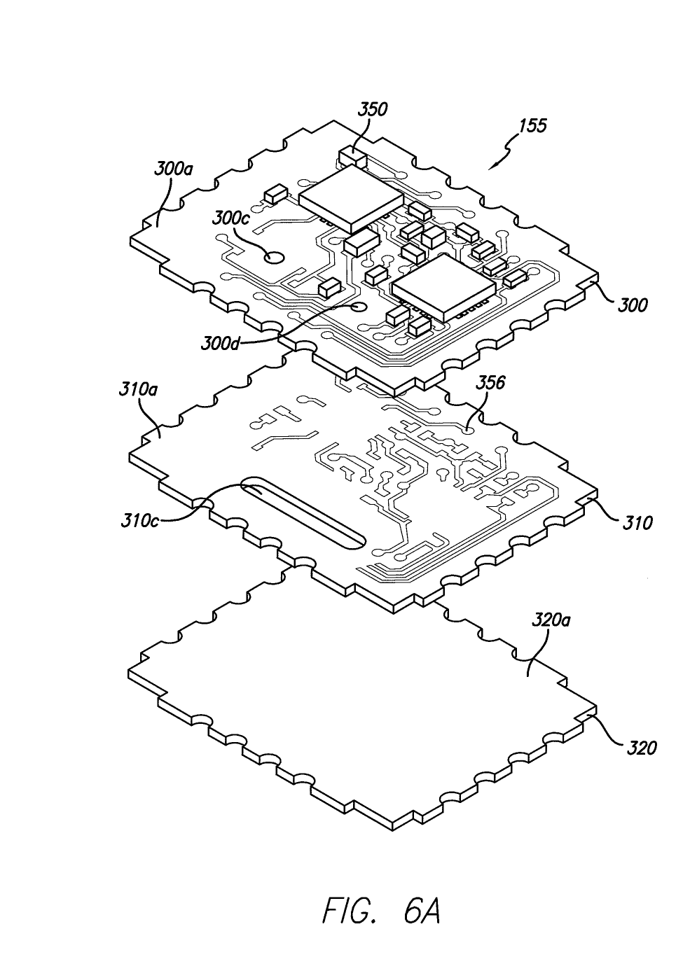

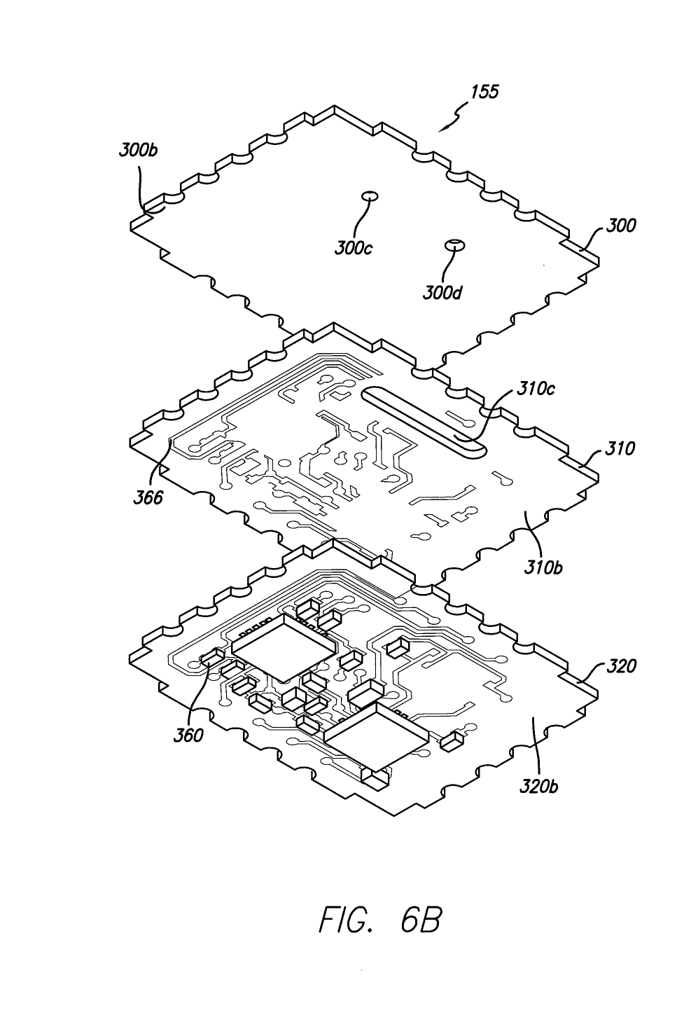

FIG. 6A is an exploded top perspective view, and FIG. 6B is an exploded bottom perspective view, of another embodiment of the PCB assembly 155 of the present invention. Referring to both FIGS. 6A and 6B, the circuit layers are applied to/disposed onto the boards as follows. A first circuit layer 350 is disposed on a top side 300a of the top board 300 and a second circuit layer 360 is disposed on a bottom side 320b of the bottom board 320. The third circuit layer 356 is disposed on a top side 310a of the center board 310 and the fourth circuit layer 366 is disposed on a bottom side 310b of the center board 310.

Referring now to FIGS. 5A-6B, the circuit layers are in electrical communication with one another. For example, as shown in FIG. 8, PCB assembly 155 also includes electrical channels (referred to herein individually and collectively as “415” and/or “circuit traces”). Preferably the circuit layers/traces at least partially define the electrical channel. These electrical channels may be formed by drilling and/or punching holes/openings through the boards. Preferably, the holes/openings for the transmission of electricity are plated with a conductor. It is to be understood that more or less circuit layers and/or boards may be used. For example, more or less center boards may be used. The circuit layers may be disposed on the boards in any configuration, as long as there is electrical communication between the layers, without departing from the scope of the present invention.

Preferably, and as shown in FIGS. 5A-6B, the PCB assembly 155 includes a plurality of openings for the transmission of pressure through the PCB assembly 155. Preferably, the openings for the transmission of pressure are arranged as follows. The top board 300 includes the first and second openings 300c and 300d, and the center board 310 includes a first elongated opening 310c.

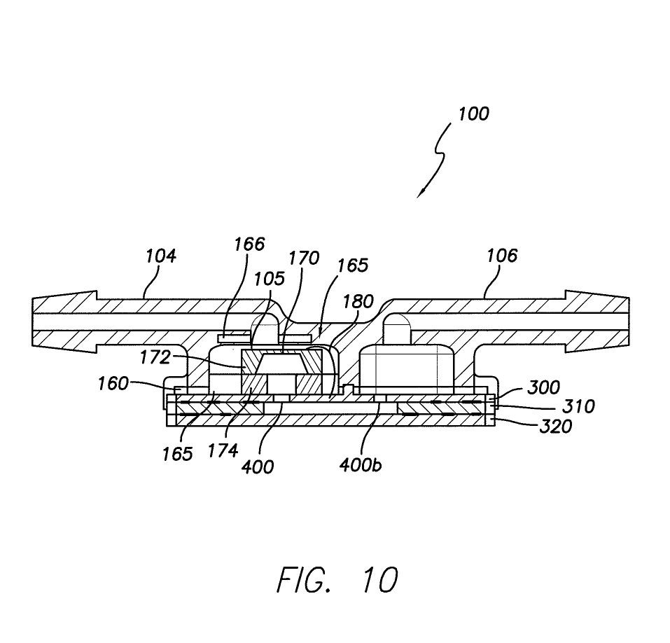

Referring to FIG. 10, it is to be understood that as the boards 300, 310, and 320 are disposed on top of one another, the alignment of the openings 300c, 300d, and 310c defines at least one pressure channel 400. As shown in FIG. 10, “400a” refers to the pressure channel that adjoins pressure port 104, and “400b” refers to the pressure channel that adjoins pressure port 106, and “400” refers to both. Preferably, the pressure channels 400a and 400b are in fluid communication with each other. The pressure channel 400 includes first elongated opening 310c, which is preferably a slot that is in fluid communication with each of the first and second openings 300c and 300d. As such, the first and second openings 300c and 300d, and the first opening 310c, together form a pressure channel 400.

In one embodiment, the first opening 300c is sealed independently from the second opening 300d to allow the gating of two different pressures, for use, for example, in a differential pressure sensor. In other embodiments, the first opening 300c is not sealed independently from the second opening 300d. Each of the boards of the PCB assembly 155 may have more or less openings, or have no openings at all. The openings described above may be created by drilling, punching, and/or any other means known in the art, and may be holes, slots, or the like.

These channels are buried inside the boards. Preferably, the pressure channel 400 is kept to a minimum volume to prevent moisture condensation while still allowing pressure to flow. Additionally, PCB assembly 155 may have more or less pressure channels; for example, pressure channel 400b may be omitted, perhaps for use as a gage pressure sensor. The pressure channels may or may not be in fluid communication with one another.

With reference to FIG. 10, the integrated pressure assembly 100 of the present invention may operate as follows. Fluid may enter pressure port 104 and travel to chimney 105. Pressure die 165 preferably resides inside chimney 105. Likewise, fluid may enter pressure port 106, travel through pressure channels 400a and 400b, and reach pressure die 165. As such, fluid from both pressure ports reaches pressure die 165. In a preferred embodiment, pressure die 165 includes a piezo-resistive sense element and/or piezo-electric sensor. This pressure die 165 preferably includes a silicon plate 172 and an apertured glass plate 174 bonded to the silicon plate 172. The silicon plate 172 is thinned down, preferably by etching, to provide a diaphragm 170. Preferably, the pressure die 165 is bonded to the first circuit layer by adhesive such as epoxy and/or silicon. Output from the pressure die 165 is preferably accomplished by wire bond leads (referred to herein individually and collectively as “180”), which are conductively connected to areas on the silicon plate 172. Preferably, the diaphragm 170 has conductive or resistive areas on its surface. The resistive areas are arranged so that, as the diaphragm 170 deflects, some of the resistive areas increase in resistance, while other areas decrease in resistance or are relatively unchanged. Using appropriate output circuitry, such as a Wheatstone bridge, the output changes are generally proportional to the applied pressure and the resulting deflection of the diaphragm 170. The resistance areas and immediately associated connections may be implemented by diffusion of n-type material or p-type material into the surface of the diaphragm 170. One pair of resistors may have the resistive areas extend circumferentially or perpendicular to a radial line from the center of the diaphragm. Coupling to external circuitry is normally accomplished by wire bonding to pad areas on the diaphragm 170. However, the diaphragm 170 may be formed of any other semiconductor and/or other material as is known in the art. Additionally, the sense element may be a piezo-resistive sense element as disclosed in U.S. Pat. No. 7,028,552, entitled, “Reliable Piezo-Resistive Pressure Sensor” to Obermeier, the entire contents of which are herein incorporated by reference. However, the pressure die 165 may include any other pressure sense element known in the art. In other embodiments, more than one sense element or pressure die may be used. Additionally, pressure die 165 may be disposed on any other PCB board/circuit layer without departing from the scope of the present invention.

The integrated pressure sensor assembly 100 of may include additional components depending on application and need. For example, and as shown in FIG. 3, the integrated pressure sensor assembly 100 may include a signal conditioning unit 395 and/or 397 disposed on the one of the boards 300, 310, or 320, or anywhere else on the structure. The signal conditioning unit 395 and/or 397 excites the sense element. If more than one signal conditioning unit is employed, it is to be understood that each may provide a different voltage. Once the pressure die 165 is excited, the output (preferably a resistance output) travels through the bond wire (or “leads”) 180 through the boards and to a CPU 395 and/or 397 (as used herein “395” or “397” refers to a signal conditioning unit and/or a CPU) either disposed on one of the boards 300, 310, or 320, or anywhere else on the structure. The CPU processes the output. However, the signal conditioning unit may be outside of the structure itself, or may be omitted.

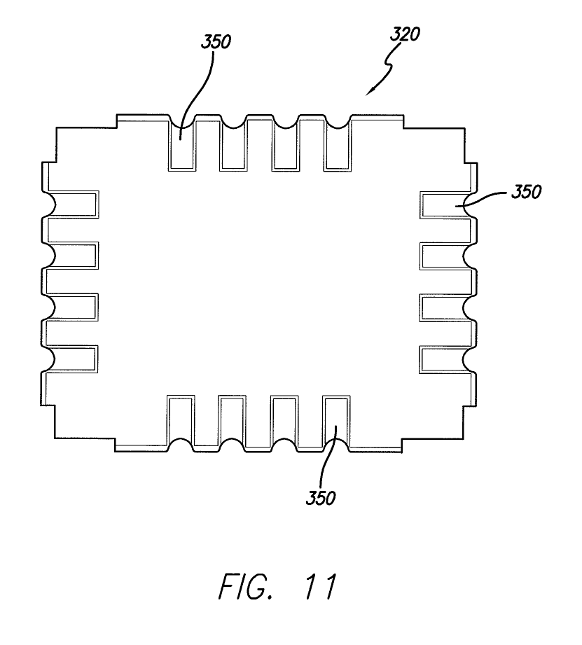

FIG. 11 shows a bottom plan view of the bottom board 320 of the PCB assembly 155 of the present invention. Preferably, the bottom board 320 includes circuit traces (not shown), PADS 350. In a preferred embodiment, the PADS are used to mount to the surface. Preferably, the PADS are used for mounting/re-flowing to a motherboard (also referred to herein as “main board” or “base board”). All the PADS, or a subset thereof, may be used for structural support and/or signal connection. In a preferred embodiment, a lead frame is not needed. Additionally, the integrated pressure assembly 100 may include structures suitable for mounting a cover. However, the PCB assembly may be mounted to a motherboard or other suitable structure using a leaded connection and/or through-hole leads. It is to be understood that the PADS may be disposed on any board. Accordingly, the PADS or other suitable structure may be disposed on boards 300, 310, 320, or any additional board for mounting and/or signal connecting to another any board.

Additionally, the integrated pressure sensor assembly 100 may also include one or more components to prevent damage from multiple re-flow. For example, the integrated pressure assembly 100 may include an eutechtic solder, wire bond for attaching internal components and/or one or more thicker PCB boards to prevent heat transfer. Additionally, a cover may be used to isolate the components from re-flow. In other embodiments, other components may be used to prevent damage from re-flow.

The embodiments described above are exemplary embodiments of the present invention. Those skilled in the art may now make numerous uses of, and departures from, the above-described embodiments without departing from the inventive concepts disclosed herein. Accordingly, the present invention is to be defined solely by the scope of the following claims.

What is claimed:

1. An integrated pressure sensor assembly comprising:
(a) a printed circuit board assembly comprising a plurality of boards;
(b) a pressure die mounted on at least a portion of the printed circuit board assembly; and
(c) a housing at least partially surrounding the printed circuit board assembly;
wherein the printed circuit board assembly comprises at least one pressure channel and at least one electrical channel, wherein the at least one pressure channel and that at least one electrical channel are both defined in at least two of the plurality of boards of the printed circuit board assembly.

2. The integrated pressure sensor assembly of claim 1, wherein the printed circuit board assembly comprises
(a) a bottom board;
(b) a top board; and
(c) at least one center board disposed between the top and bottom boards.

3. The integrated pressure sensor assembly of claim 2, wherein the top board comprises a first opening and a second opening that each partially define a portion of the pressure channel.

4. The integrated pressure sensor assembly of claim 3, wherein the at least one center board comprises a first opening, wherein the first opening in the at least one center board is in flow communication with the first opening in the top board.

5. The integrated pressure sensor assembly of claim 4, wherein the first opening in the at least one center board is a slot, and wherein the first opening in the at least one center board is in flow communication with the second opening in the top board.

6. The integrated pressure sensor assembly of claim 1, wherein the housing comprises at least one pressure port.

7. The integrated pressure sensor assembly of claim 1, wherein a circuit layer is disposed on each of a top side of the top board and a bottom side of the bottom board.

8. The integrated pressure sensor assembly of claim 7, wherein a circuit layer is disposed on each of a top side of the at least one center board and a bottom side of the at least one center board, and wherein the circuit layers at least partially define the electrical channel.

9. The integrated pressure sensor assembly of claim 7, wherein a circuit layer is disposed on each of a bottom of the top board and a top of the bottom board, and wherein the circuit layers at least partially define the electrical channel.

10. A method comprising:
(a) providing a printed circuit board assembly comprising:
(i) a bottom board;
(ii) a top board; and
(iii) at least one center board disposed between the top and bottom boards;
(b) providing a pressure die disposed on at least a portion of the printed circuit board assembly; and
(c) providing a housing, wherein the housing at least partially surrounds the printed circuit board assembly;
wherein the printed circuit board assembly comprises at least one fluid transmission channel and at least one electrical transmission channel, wherein the at least one fluid transmission channel and the at least one electrical transmission channel are both defined in at least two of the bottom board, the top board and the at least one center board.

11. The integrated pressure sensor assembly of claim 1, wherein the pressure die is a piezoelectric sensor.

12. The method of claim 10, further comprising defining a first opening and a second opening in the top board, wherein each partially define a portion of the fluid transmission channel.

13. The method of claim 12, further comprising defining a first opening in the at least one center board, wherein the first opening in the at least one center board is in flow communication with the first opening in the top board.

14. The method of claim 13, wherein the first opening in the at least one center board is a slot, and wherein the first opening in the at least one center board is in flow communication with the second opening in the top board.

15. The method of claim 14, further comprising the step of aligning the first and second openings on the top board with the first opening on the center board to at least partially define the fluid transmission channel.

16. A printed circuit board assembly comprising:
(a) a bottom board;
(b) a top board; and
(c) at least one center board disposed between the top and bottom boards;
wherein the printed circuit board assembly comprises at least one fluid channel and at least one electrical channel at least partially therethrough, wherein the at least one fluid channel and the at least one electrical channel are both defined in at least two of the bottom board, the top board and the at least one center board.

17. The printed circuit board assembly of claim 16, wherein the fluid channel extends through at least two of the top, bottom, and center boards.

18. The printed circuit board assembly of claim 16, wherein the fluid channel provides flow communication between at least two of the boards and wherein the electrical channel provides electrical communication between at least two of the boards.

19. The printed circuit board assembly of claim 16, further comprising a sense element at least partially disposed on a portion of the printed circuit board assembly, wherein the sense element measures pressure in the fluid channel.

20. The printed circuit board assembly of claim 19, wherein the sense element is at least partially disposed over a first opening on the top board, wherein the first opening at least partially defines the fluid channel.
